(19) United States
(12) Patent Application Publication
(10) Pub. No.: US 2022/0027080 A1
(43) Pub. Date: Jan. 27, 2022

(54) METHOD AND SYSTEM FOR A SEQUENCE AWARE DATA INGEST AND A SEQUENCE AWARE REPLICATION BETWEEN DATA CLUSTERS

(71) Applicant: Dell Products L.P., Hopkinton, MA (US)

(72) Inventors: Dharmesh M. Patel, Round Rock, TX (US); Ravikanth Chaganti, Bangalore (IN)

(21) Appl. No.: 16/936,492

(22) Filed: Jul. 23, 2020

(51) Int. Cl. G06F 3/06; G06F 16/16; H03M 13/15

(52) U.S. Cl. CPC G06F 3/0655; G06F 3/0676; H03M 13/154; G06F 3/0604; G06F 16/164; G06F 3/0679

(57) ABSTRACT

A method for managing data includes obtaining data from a host, performing an erasure coding procedure to the data to obtain a plurality of slices, wherein each slice in the plurality of slices comprises a plurality of data chunks and at least one parity chunk, generating a plurality of segment entries, wherein each segment entry in the plurality of segment entries specifies a segment, generating metadata slice entries, wherein each metadata slice entry is associated with a slice in the plurality of slices, storing the plurality of segment entries and the metadata slice entries in an accelerator pool in a first data cluster, and storing, across a plurality of fault domains in the first data cluster, the data chunks and the parity chunk of each slice in the plurality of slices based on the plurality of segment entries.

### BACKGROUND

Computing devices may include any number of internal components such as processors, memory, and persistent storage. Each of the internal components of a computing device may be used to generate data. The process of generating, storing, and backing-up data may utilize computing resources of the computing devices such as processing and storage. The utilization of the aforementioned computing resources to generate backups may impact the overall performance of the computing resources.

### SUMMARY

In general, in one aspect, the invention relates to a method for managing data. The method includes obtaining data from a host, performing an erasure coding procedure to the data to obtain a plurality of slices, wherein each slice in the plurality of slices comprises a plurality of data chunks and at least one parity chunk, generating a plurality of segment entries, wherein each segment entry in the plurality of segment entries specifies a segment, generating a plurality of metadata slice entries, wherein each metadata slice entry in the plurality of metadata slice entries is associated with a slice in the plurality of slices, storing the plurality of segment entries and the plurality of metadata slice entries in an accelerator pool in a first data cluster, and storing, across a plurality of fault domains in the first data cluster, the plurality of data chunks and the at least one parity chunk of each slice in the plurality of slices based on the plurality of segment entries.

In general, in one aspect, the invention relates to a non-transitory computer readable medium which includes computer readable program code, which when executed by a computer processor enables the computer processor to perform a method for managing data. The method includes obtaining data from a host, performing an erasure coding procedure to the data to obtain a plurality of slices, wherein each slice in the plurality of slices comprises a plurality of data chunks and at least one parity chunk, generating a plurality of segment entries, wherein each segment entry in the plurality of segment entries specifies a segment, generating a plurality of metadata slice entries, wherein each metadata slice entry in the plurality of metadata slice entries is associated with a slice in the plurality of slices, storing the plurality of segment entries and the plurality of metadata slice entries in an accelerator pool in a first data cluster, and storing, across a plurality of fault domains in the first data cluster, the plurality of data chunks and the at least one parity chunk of each slice in the plurality of slices based on the plurality of segment entries.

In general, in one aspect, the invention relates to a data cluster that includes a data processor and memory that includes instructions, which when executed by the data processor perform a method. The method includes obtaining data from a host, performing an erasure coding procedure to the data to obtain a plurality of slices, wherein each slice in the plurality of slices comprises a plurality of data chunks and at least one parity chunk, generating a plurality of segment entries, wherein each segment entry in the plurality of segment entries specifies a segment, generating a plurality of metadata slice entries, wherein each metadata slice entry in the plurality of metadata slice entries is associated with a slice in the plurality of slices, storing the plurality of segment entries and the plurality of metadata slice entries in an accelerator pool in a first data cluster, and storing, across a plurality of fault domains in the first data cluster, the plurality of data chunks and the at least one parity chunk of each slice in the plurality of slices based on the plurality of segment entries.

### BRIEF DESCRIPTION OF DRAWINGS

Certain embodiments of the invention will be described with reference to the accompanying drawings. However, the accompanying drawings illustrate only certain aspects or implementations of the invention by way of example and are not meant to limit the scope of the claims.

FIG. 1A shows a diagram of a system in accordance with one or more embodiments of the invention.

FIG. 1B shows a diagram of a data cluster in accordance with one or more embodiments of the invention.

FIG. 1C shows a diagram of a data node in accordance with one or more embodiments of the invention.

FIG. 1D shows a diagram of persistent storage in accordance with one or more embodiments of the invention.

FIG. 1E shows a diagram of a non-accelerator pool in accordance with one or more embodiments of the invention.

FIG. 2A shows a diagram of storage metadata in accordance with one or more embodiments of the invention.

FIG. 2B shows a diagram of object metadata in accordance with one or more embodiments of the invention.

FIG. 3A shows a flowchart for storing data in a data cluster in accordance with one or more embodiments of the invention.

FIG. 3B shows a flowchart for replicating data to a second data cluster in accordance with one or more embodiments of the invention.

FIGS. 4A-4B show an example in accordance with one or more embodiments of the invention.

FIG. 5 shows a diagram of a computing device in accordance with one or more embodiments of the invention.

### DETAILED DESCRIPTION

Specific embodiments will now be described with reference to the accompanying figures. In the following description, numerous details are set forth as examples of the invention. It will be understood by those skilled in the art that one or more embodiments of the present invention may be practiced without these specific details and that numerous variations or modifications may be possible without departing from the scope of the invention. Certain details known to those of ordinary skill in the art are omitted to avoid obscuring the description.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment, which may be implemented in addition to, in conjunction with, or in place of the embodiments described with regard to a corresponding like-named component in any other figure.

Throughout this application, elements of figures may be labeled as A to N. As used herein, the aforementioned labeling means that the element may include any number of items and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure and the number of elements of the second data structure may be the same or different.

In general, embodiments of the invention relate to a method and system for storing data and metadata in a data cluster. Embodiments of the invention may utilize a data processor, operating in an accelerator pool, which applies an erasure coding procedure on data obtained from a host to divide the data into data chunks and to generate parity chunks using the data chunks. The data processor may then perform deduplication on the data chunks to generate deduplicated data that includes deduplicated data chunks. The deduplicated data chunks and the parity chunks are subsequently distributed to nodes in the data cluster in accordance with an erasure coding procedure.

In one or more embodiments of the invention, the accelerator pool stores storage metadata that specifies the nodes in which each data chunk and parity chunk is stored and object metadata that specifies an object associated with each data chunk. The storage metadata and object metadata may also be distributed to nodes in the non-accelerator pool. In this manner, if the storage metadata or object metadata stored in the accelerator pool becomes unavailable, the storage metadata may be reconstructed using the storage metadata and object metadata stored in the non-accelerator pool.

In one or more embodiments of the invention, the data stored within the fault domains is tracked within the nodes and/or persistent storage devices to maintain segments of data. The data chunks or parity chunks in a segment may be stored sequentially in the corresponding persistent storage device to maintain contiguous data for the segment. The segment metadata may be tracked using the storage metadata. The storage metadata may be used during a replication of the data in a data cluster to a second data cluster. In this manner, the segments of contiguous data is maintained in the replicated data cluster.

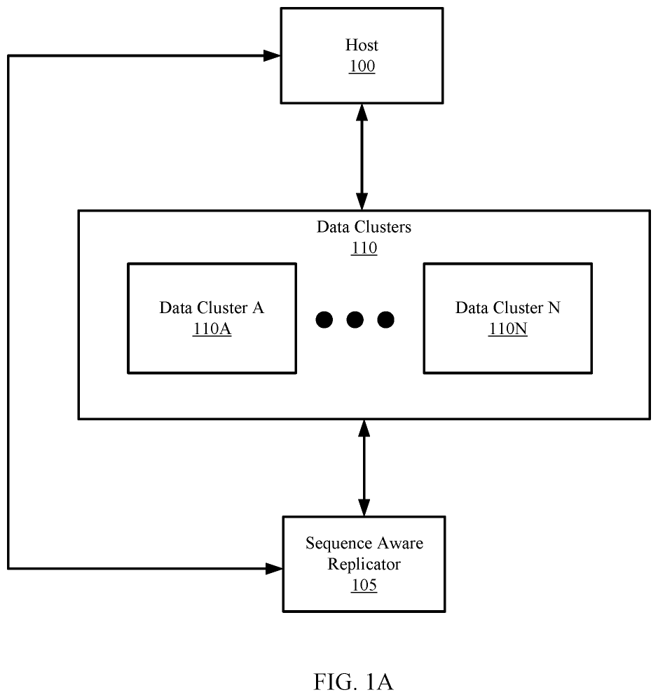

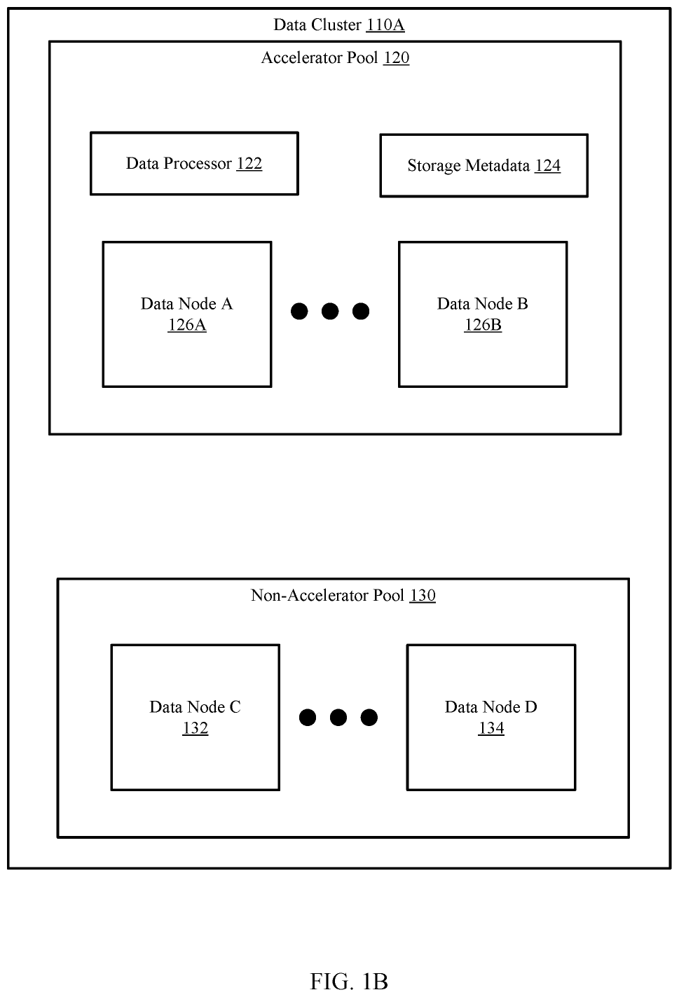

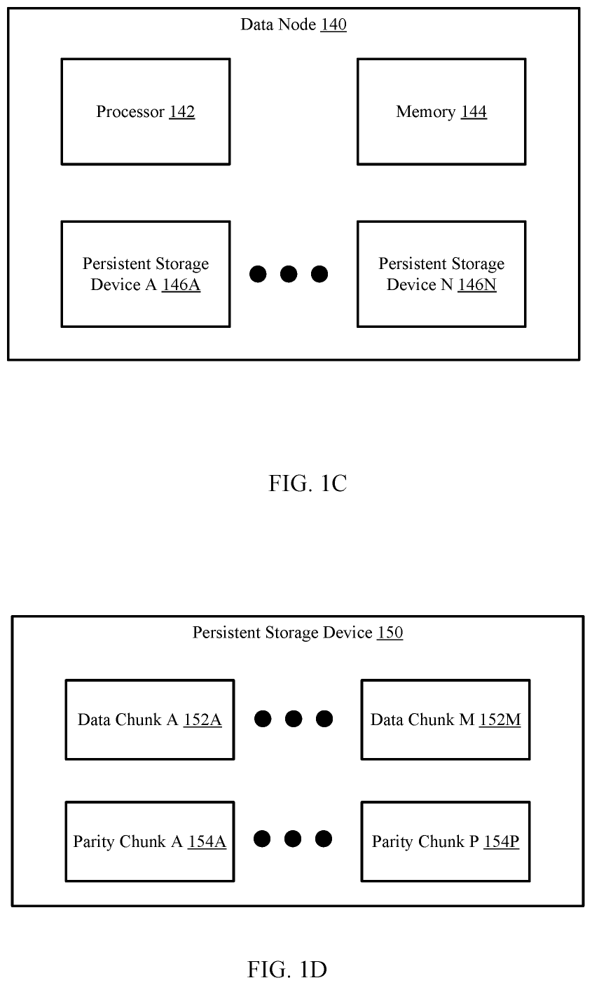

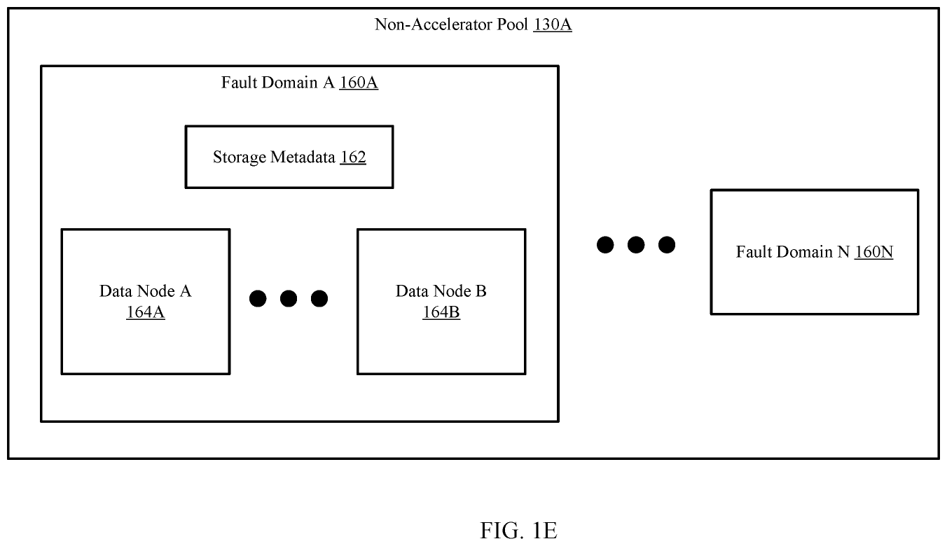

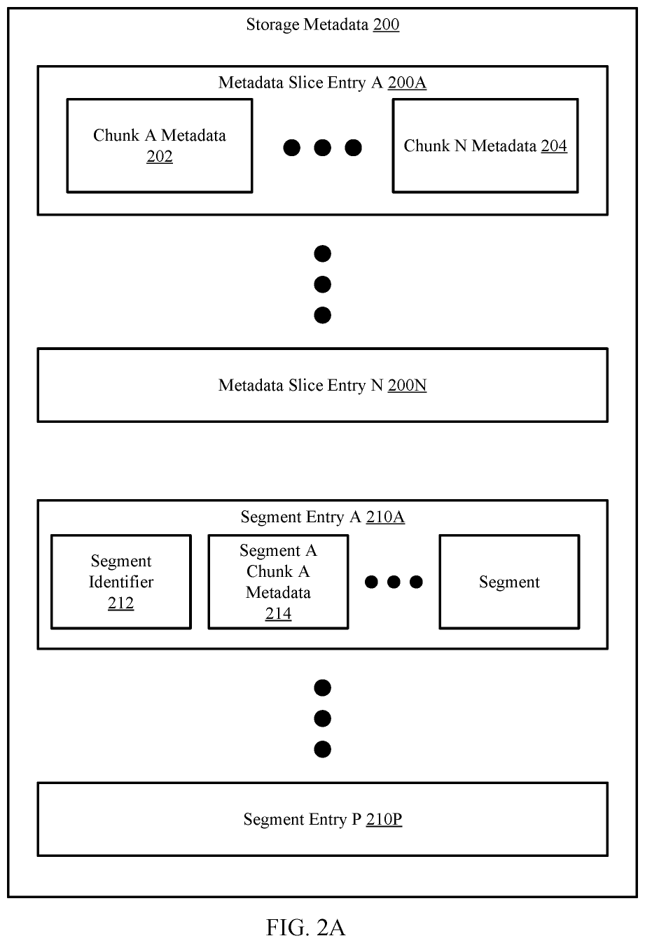

FIG. 1A shows an example system in accordance with one or more embodiments of the invention. The system includes a host (100), two or more data clusters (110), and a sequence aware replicator (105). The system may include additional, fewer, and/or different components without departing from the invention. Each of the components in the system may be operably connected via any combination of wired and/or wireless connections.

In one or more embodiments of the invention, the host (100) utilizes at least one data cluster (e.g., 110A) to store data. The data stored may be backups of databases, files, applications, and/or other types of data without departing from the invention.

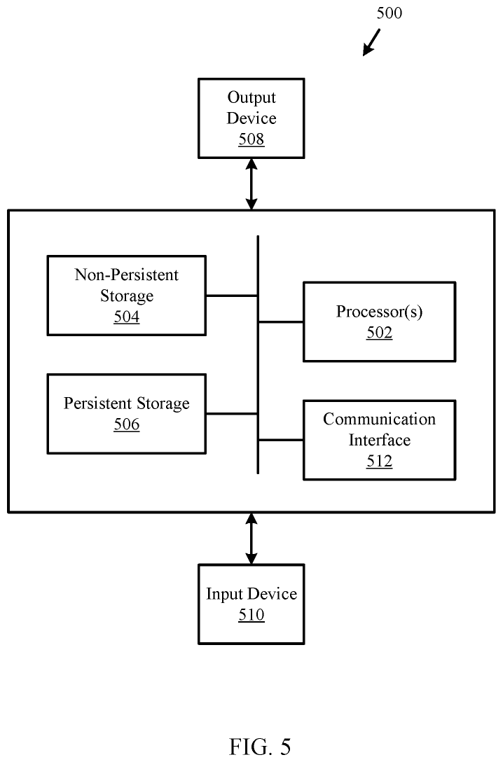

In one or more embodiments of the invention, the host (100) is implemented as a computing device (see e.g., FIG. 5). The computing device may be, for example, a laptop computer, a desktop computer, a server, a distributed computing system, or a cloud resource (e.g., a third-party storage system accessible via a wired or wireless connection). The computing device may include one or more processors, memory (e.g., random access memory), and persistent storage (e.g., disk drives, solid state drives, etc.). The computing device may include instructions, stored on the persistent storage, that when executed by the processor(s) of the computing device cause the computing device to perform the functionality of the host (100) described throughout this application.

In one or more embodiments of the invention, the host (100) is implemented as a logical device. The logical device may utilize the computing resources of any number of computing devices and thereby provide the functionality of the host (100) described throughout this application.

In one or more embodiments of the invention, each data cluster (110A, 110N) stores data, metadata, and/or replicas of data generated by the host (100). The data and/or replicas may be deduplicated versions of data obtained from the host. The data cluster may, via an erasure coding procedure, store portions of the deduplicated data across nodes operating in the data cluster (110A, 110N).

As used herein, deduplication refers to methods of storing only portions of files (also referred to as file fragment or fragment) that are not already stored in persistent storage. For example, when multiple versions of a large file, having only minimal differences between each of the versions, are stored without deduplication, storing each version will require approximately the same amount of storage space of a persistent storage. In contrast, when the multiple versions of the large file are stored with deduplication, only the first version of the multiple versions stored will require a substantial amount of storage. Once the first version is stored in the persistent storage, the subsequent versions of the large file subsequently stored will be de-duplicated before being stored in the persistent storage resulting in much less storage space of the persistent storage being required to store the subsequently stored versions when compared to the amount of storage space of the persistent storage required to store the first stored version.

Continuing with the discussion of FIG. 1A, a data cluster (e.g., 110A, 110N) may include nodes that each store any number of portions of data. The portions of data may be obtained by other nodes or obtained from the host (100). For additional details regarding the data cluster (110), see, e.g., FIG. 1B.

In one or more embodiments of the invention, the sequence aware replicator (105) includes functionality for replicating data from one data cluster (e.g., 110A) to a second data cluster (e.g., 110N). The sequence aware replicator (105) may obtain storage metadata (discussed below) from the first data cluster (110A) to be used during the replication of the data in the first data cluster (110A) to the second data cluster (110N).

In one or more embodiments of the invention, the sequence aware replicator (105) is implemented as a computing device (see e.g., FIG. 5). The computing device may be, for example, a laptop computer, a desktop computer, a server, a distributed computing system, or a cloud resource (e.g., a third-party storage system accessible via a wired or wireless connection). The computing device may include one or more processors, memory (e.g., random access memory), and persistent storage (e.g., disk drives, solid state drives, etc.). The computing device may include instructions, stored on the persistent storage, that when executed by the processor(s) of the computing device cause the computing device to perform the functionality of the sequence aware replicator (105) described throughout this application.

In one or more embodiments of the invention, the sequence aware replicator (105) is implemented as a logical device. The logical device may utilize the computing resources of any number of computing devices and thereby provide the functionality of the sequence aware replicator (105) described throughout this application.

FIG. 1B shows a diagram of a data cluster (110A) in accordance with one or more embodiments of the invention. The data cluster (110A) may be an embodiment of the data cluster (110A, FIG. 1A) discussed above. The data cluster (110A) may include an accelerator pool (120) and a non-accelerator pool (130). The accelerator pool (120) may include a data processor (122), storage metadata (124), object metadata (128) and any number of data nodes (126A, 126B). Similarly, the non-accelerator pool (130) includes any number of data nodes (132, 134). The components of the data cluster (110A) may be operably connected via any combination of wired and/or wireless connections. Each of the aforementioned components is discussed below.

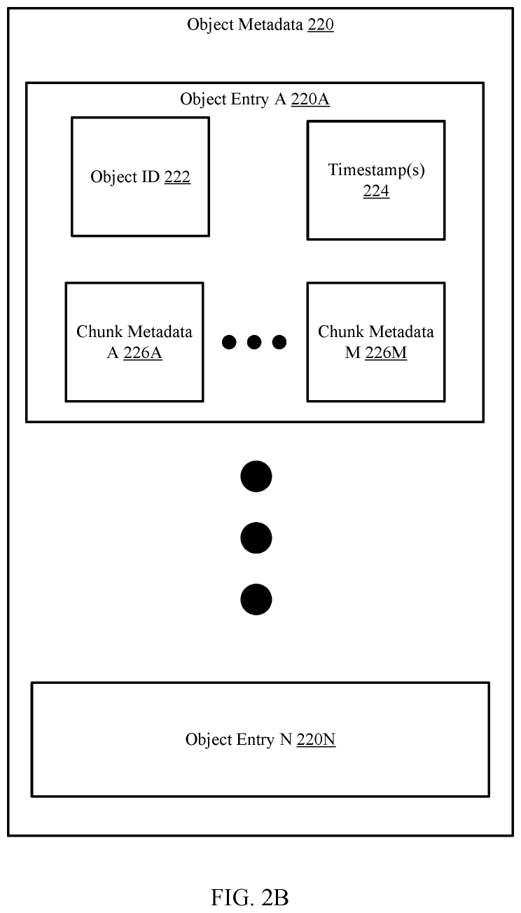

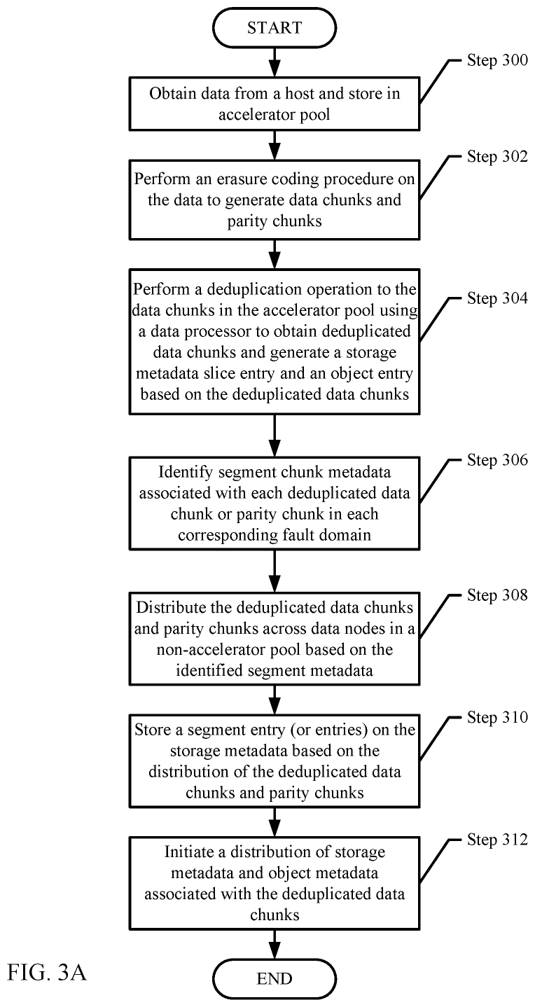

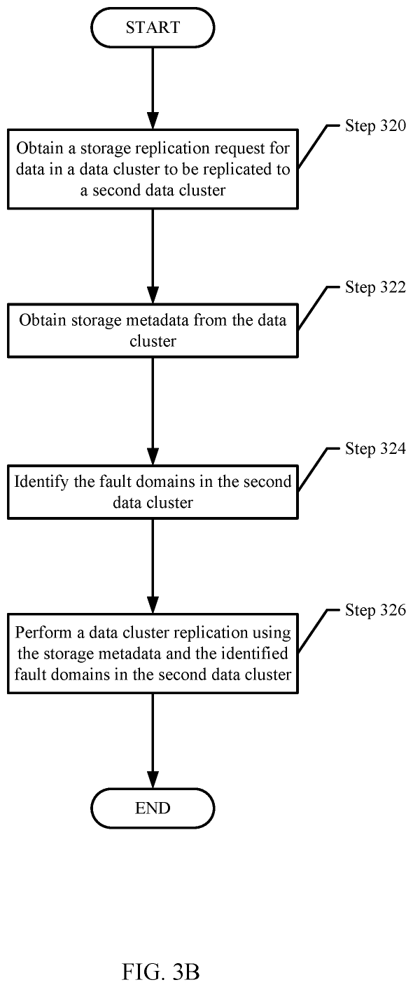

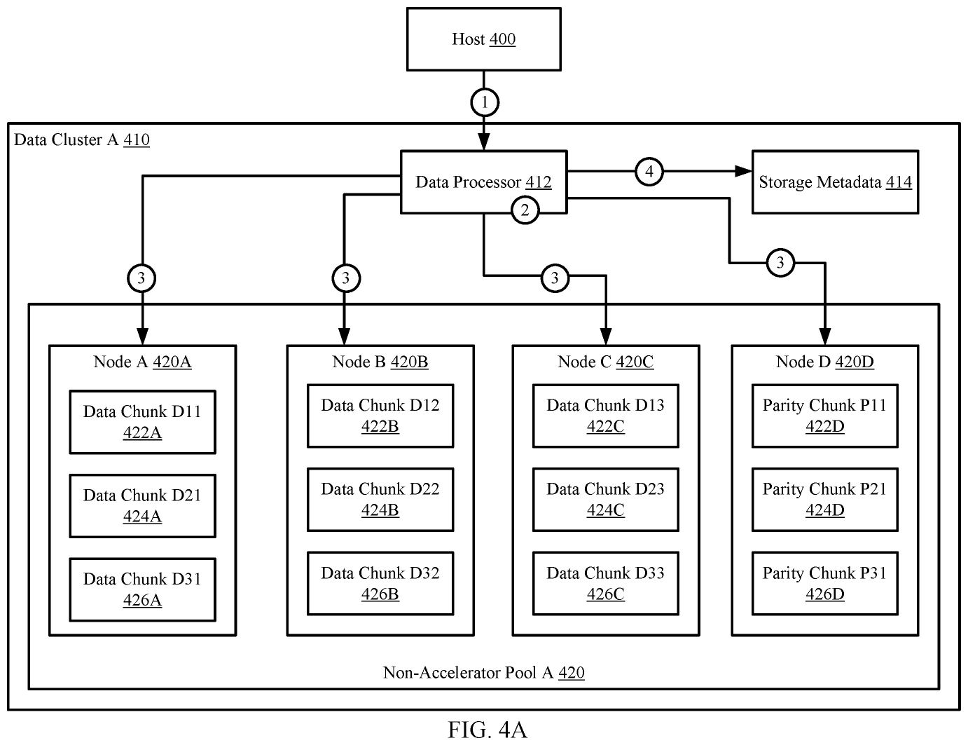

In one or more embodiments of the invention, the data processor (122) is a device that includes functionality to perform erasure coding and/or deduplication on data obtained from a host (e.g., 100, FIG. 1A). The data processor (122) may generate, utilize, and update storage metadata (124) (as described in FIG. 2A) as part of its deduplication functionality. In one or more embodiments of the invention, the storage metadata (124) is a data structure that stores unique identifiers of portions data stored in the data cluster (110A). The unique identifiers stored in the storage metadata (124) may be used to determine whether a data chunk of the obtained data is already present elsewhere in the accelerator pool (120) or the non-accelerator pool (130). The data processor (122) may use the storage information to perform the deduplication and generate deduplicated data. The data processor (122) may perform the deduplication and erasure coding procedure via the method illustrated in FIG. 3A.

In one or more embodiments of the invention, the storage metadata (124) is stored in a data node (126A, 126B) of the accelerator pool (120). A copy of the storage metadata (124) may be distributed to one or more data nodes (132, 134) of the non-accelerator pool (130). In this manner, if the storage metadata (124) stored in the accelerator pool (120) experiences a failure (e.g., it becomes unavailable, corrupted, etc.), the storage metadata (124) may be reconstructed using the copies of storage metadata stored in the non-accelerator pool (130). For additional detail regarding the distribution on storage metadata, see e.g., FIG. 3A.

In one or more embodiments of the invention, the data processor (122) updates object metadata (128) after storing data chunks (which may be deduplicated data chunks) and parity chunks. In one or more embodiments of the invention, the object metadata is a data structure, stored in a computing device (e.g., a data node (126A, 126B)) of the accelerator pool (120), which includes object information about the data stored in the data cluster (110A). An object may be, for example, a file, a set of files, a portion of a file, a backup of any combination thereof, and/or any other type of data without departing from the invention. For additional details regarding the object metadata, see, e.g., FIG. 2B.

In one or more of embodiments of the invention, the data processor (122) is implemented as computer instructions, e.g., computer code, stored on a persistent storage that when executed by a processor of a data node (e.g., 126A, 126B) of the accelerator pool (120) cause the data node to provide the aforementioned functionality of the data processor (122) described throughout this application and/or all, or a portion thereof, of the method illustrated in FIG. 3A.

In one or more embodiments of the invention, the data processor (122) is implemented as a computing device (see e.g., FIG. 5). The computing device may be, for example, a laptop computer, a desktop computer, a server, a distributed computing system, or a cloud resource (e.g., a third-party storage system accessible via a wired or wireless connection). The computing device may include one or more processors, memory (e.g., random access memory), and persistent storage (e.g., disk drives, solid state drives, etc.). The computing device may include instructions, stored on the persistent storage, that when executed by the processor(s) of the computing device cause the computing device to perform the functionality of the data processor (122) described throughout this application and/or all, or a portion thereof, of the method illustrated in FIGS. 3A-3B.

In one or more embodiments of the invention, the data processor (122) is implemented as a logical device. The logical device may utilize the computing resources of any number of computing devices and thereby provide the functionality of the data processor (122) described throughout this application and/or all, or a portion thereof, of the method illustrated in FIG. 3A.

Continuing with the discussion of FIG. 1B, different data nodes in the cluster may include different quantities and/or types of computing resources, e.g., processors providing processing resources, memory providing memory resources, storages providing storage resources, communicators providing communications resources. Thus, the system may include a heterogeneous population of nodes.

The heterogeneous population of nodes may be logically divided into: (i) an accelerator pool (120) including nodes that have more computing resources, e.g., high performance nodes (126A, 126B), than other nodes and (ii) a non-accelerator pool (130) including nodes that have fewer computing resources, e.g., low performance nodes (132, 134) than the nodes in the accelerator pool (120). For example, nodes of the accelerator pool (120) may include enterprise-class solid state storage resources that provide very high storage bandwidth, low latency, and high input-outputs per second (IOPS). In contrast, the nodes of the non-accelerator pool (130) may include hard disk drives that provide lower storage performance. While illustrated in FIG. 1B as being divided into two groups, the nodes may be divided into any number of groupings based on the relative performance level of each node without departing from the invention.

In one or more embodiments of the invention, the data nodes (126A, 126B, 132, 134) store data chunks and parity chunks along with storage metadata and object metadata (as described below). The data nodes (126A, 126B, 132, 134) may include persistent storage that may be used to store the data chunks, parity chunks and storage metadata. The generation of the data chunks and parity chunks as well as the storage metadata is described below with respect to FIG. 3A. For additional details regarding the data nodes (126A, 126B, 132, 134), see, e.g., FIG. 1C.

In one or more embodiments of the invention, the non-accelerator pool (130) includes any number of fault domains. In one or more embodiments of the invention, a fault domain is a logical grouping of nodes (e.g., data nodes) which, when one node of the logical grouping of nodes goes offline and/or otherwise becomes inaccessible, the other nodes in the same logical grouping of nodes are directly affected. However, nodes in a different fault domain may be unaffected. For additional details regarding fault domains, see, e.g. FIG. 1E.

In one or more embodiments of the invention, each data node (126A, 126B, 132, 134) is implemented as a computing device (see e.g., FIG. 5). The computing device may be, for example, a laptop computer, a desktop computer, a server, a distributed computing system, or a cloud resource (e.g., a third-party storage system accessible via a wired or wireless connection). The computing device may include one or more processors, memory (e.g., random access memory), and persistent storage (e.g., disk drives, solid state drives, etc.). The computing device may include instructions, stored on the persistent storage, that when executed by the processor(s) of the computing device cause the computing device to perform the functionality of the data node (126A, 126B, 132, 134) described throughout this application and/or all, or a portion thereof, of the method illustrated in FIGS. 3A-3B.

In one or more embodiments of the invention, each of the data nodes (126A, 126B, 132, 134) is implemented as a logical device. The logical device may utilize the computing resources of any number of computing devices and thereby provide the functionality of the data nodes (126A, 126B, 132, 134) described throughout this application and/or all, or a portion thereof, of the method illustrated in FIGS. 3A-3B. For additional details regarding the data nodes (126A, 126B, 132, 134), see, e.g., FIG. 1C.

FIG. 1C shows a diagram of a data node (140) in accordance with one or more embodiments of the invention. The data node (140) may be an embodiment of a data node (126A, 126B, 132, 134, FIG. 1B) discussed above. Each data node may be equipped with a processor (142), memory (144), and one or more persistent storage devices (146A, 146N). Each component of the data node (140) may be operatively connected to each other via wired and/or wireless connections. The data node (140) may have additional, fewer, and/or different components without departing from the invention. Each of the illustrated components of the data node (140) is discussed below.

In one or more embodiments of the invention, the processor (142) is a component that processes data and/or processes requests. The processor (142) may be, for example, a central processing unit (CPU). The processor may process object rebuild request and/or requests to rebuild data and/or metadata using data stored in memory (144) and/or the persistent storage devices (146A, 146N). The processor (142) may process other requests without departing from the invention.

In one or more embodiments of the invention, the data node includes memory (144), which stores data that is more accessible to the processor (142) than the persistent storage devices (146A, 146N). The memory (144) may be volatile storage. Volatile storage may be storage that stores data that is lost when the storage loses power. The memory may be, for example, Random Access Memory (RAM). In one or more embodiments of the invention, a copy of the storage metadata discussed in FIG. 1B is stored in the memory (144) of the data node (140).

In one or more embodiments of the invention, the persistent storage devices (146A, 146N) store data. The data may be data chunks and/or parity chunks. In addition, the data may also include storage metadata. The persistent storage devices (146A, 146N) may be non-volatile storage. In other words, the data stored in the persistent storage devices (146A, 146N) is not lost or removed when the persistent storage devices (146A, 146N) lose power. Each of the persistent storage devices (146A, 146N) may be, for example, solid state drives, hard disk drives, and/or tape drives. The persistent storage devices may include other types of non-volatile or non-transitory storage mediums without departing from the invention. For additional details regarding the persistent storage devices, see, e.g., FIG. 1D.

FIG. 1D shows a diagram of a persistent storage device. The persistent storage device (150) may be an embodiment of a persistent storage device (146A, 146N) discussed above. As discussed above, the persistent storage device (150) stores data. The data may be data chunks (152A, 152M) and parity chunks (154A, 154P). Though not shown in FIG. 1D, the data may also include storage metadata

In one or more embodiments of the invention, a data chunk (152A, 152M) is a data structure that includes a portion of data that was obtained from a host. The data chunks (152A, 152M) may be deduplicated by a data processor and obtained by the data node (140) from the data processor. Each of the data chunks (152A, 152M) may be used by the data node (140) (or another data node) to reconstruct another data chunk or a parity chunk based on an erasure coding algorithm that was applied to the other data chunk or parity chunk.

In one or more embodiments of the invention, a parity chunk (154A, 154P) is a data structure that includes a parity value generated using an erasure coding algorithm. The parity value may be generated by applying the erasure coding algorithm to one or more data chunks stored in the data node (140) or other data nodes. Each of the parity chunks (154A, 154P) may be used by the data node (140) (or another data node) to reconstruct another parity chunk or a data chunk based on an erasure coding algorithm that was applied to the other parity chunk or data chunk.

In one or more embodiments of the invention, the storage of the data chunks (e.g., 152A, 152M) and the parity chunks (154A, 154P) may be tracked by the storage metadata (e.g., discussed in FIG. 2). Further, the data chunks and parity chunks may be stored in the persistent storage device (150) based on segments of data (discussed in FIG. 2A). For example, the data chunks in a segment of data may be stored contiguously (e.g., along a continuous portion of the persistent storage device (150). The segment of data may be stored in any other order without departing from the invention.

FIG. 1E shows a diagram of a non-accelerator pool in accordance with one or more embodiments of the invention. The non-accelerator pool (130A) is an embodiment of the non-accelerator pool (130, FIG. 1B) discussed above. The non-accelerator pool (130A) may include any number of fault domains (160A, 160N).

As discussed above, a fault domain (160A, 160N) is a logical grouping of data nodes (164A, 164B) that, when one data node of the logical grouping of data nodes goes offline and/or otherwise becomes inaccessible, the other nodes in the logical grouping of nodes are directly affected. The effect of the node going offline to the other nodes may include the other nodes also going offline and/or otherwise inaccessible. The non-accelerator pool (130) may include multiple fault domains. In this manner, the events of one fault domain in the non-accelerator pool (130A) may have no effect to other fault domains in the non-accelerator pool (130A).

For example, two data nodes may be in a first fault domain (e.g., 160A). If one of these data nodes in the first fault domain (160A) experiences an unexpected shutdown, other nodes in the first fault domain may be affected. In contrast, another data node in a second fault domain may not be affected by the unexpected shutdown of a data node in the first fault domain. In one or more embodiments of the invention, the unexpected shutdown of one fault domain does not affect the nodes of other fault domains. In this manner, data may be replicated and stored across multiple fault domains to allow high availability of the data.

As discussed above, the data chunks and parity chunks (e.g., generated using the erasure coding described in FIG. 3A) may be stored in different fault domains (160A, 160N). Storing the data chunks and parity chunks in multiple fault domains may be for recovery purposes. In the event that one or more fault domains storing data chunks or parity chunks become inaccessible, the data chunks and/or parity chunks stored in the remaining fault domains may be used to recreate the inaccessible data. In one embodiment of the invention, as part of (or in addition to) the chunk metadata, the storage metadata (162) tracks the related data chunks and parity chunks (i.e., which data chunks and which parity chunks are associated with a metadata slice). This information may be used to aid in any recover operation that is required to be performed on the data stored in the data cluster.

In one or more embodiments of the invention, each fault domain (160A, 160N) stores a copy of storage metadata (162) and a copy of object metadata (166) obtained from an accelerator pool and/or from another fault domain (160A, 160N) distributing a copy of the storage metadata. The copy of storage metadata (162) and the copy of the object metadata (166) in a fault domain (e.g., 160A) may each be stored in one or more data nodes (164A, 164B) of the fault domain. The copy of storage metadata (162) and the copy of object metadata (166) may each be stored in any other computing device associated with the fault domain (160A) without departing from the invention.

FIG. 2A shows a diagram of storage metadata in accordance with one or more embodiments of the invention. The storage metadata (200) may be an embodiment of the storage metadata (124, FIG. 1B; 162, FIG. 1E) discussed above. As discussed above, the storage metadata (200) stores information about data chunks or parity chunks (collectively, chunks). The storage information may include one or more metadata slice entries (200A, 200N) and one or more segment entries (210A, 210P). Each metadata slice entry (200A, 200N) may include chunk metadata (202, 204). Each of the aforementioned portions of the storage metadata (200) is discussed below.

In one or more embodiments of the invention, a metadata slice entry (200A, 200N) is an entry that specifies metadata associated with chunks of a data and parity generated using an erasure coding procedure. The metadata slice entry (200A, 200N) includes chunk metadata (202, 204). Each chunk of a chunk metadata (202, 204) may correspond to metadata for a data chunk or a parity chunk. Each chunk metadata (202, 204) may include information about a chunk such as, for example, a unique identifier (e.g., a fingerprint) and a storage location of the chunk, e.g., the non-accelerator pool. The unique identifier of a chunk may be generated using the chunk (e.g., calculated using the data of the chunk).

In one or more embodiments of the invention, each segment entry (210A, 210P) includes a segment identifier (212) and segment chunk metadata (214, 216). In one or more embodiments of the invention, a segment is a grouping of data chunks and/or parity chunks of an object that are each associated with a different slice but stored in the same fault domain. For example, an object may comprise four slices (e.g., four portions of data that may each include data chunks and parity chunks that may be used to recreate other chunks in the portion). Each slice may include five data chunks and/or parity chunks. Each chunk (e.g., a data chunk or parity chunk) may be stored in a fault domain. The four chunks (which may be any combination of data chunks and/or parity chunks) (i.e., one from each of the four slices) stored in a first fault domain may be associated with a first segment, the four chunks (i.e., one from each of the four slices) stored in a second fault domain may be associated with a second segment, etc. In one or more embodiments of the invention, the segment identifier is any combination of letters, numbers, and/or symbols that uniquely identifies the segment of the segment entry.

In one or more embodiments of the invention, the segment chunk metadata (214) specifies the storage information of a segment chunk relative to the other segment chunks in the segment. For example, the segment A chunk A metadata (214) may specify being stored first in the segment relative to the segment chunks in the segment. Further, the segment A chunk A metadata (214) may specify the storage location of the segment chunk in the persistent storage device.

FIG. 2B shows a diagram of object metadata in accordance with one or more embodiments of the invention. The object metadata (210) may be an embodiment of the storage metadata (128, FIG. 1B; 166, FIG. 1E) discussed above. As discussed above, the object metadata (210) stores information about objects. The object metadata (210) may include one or more object entries (210A, 210N). Each object entry (210A, 210N) may include an object ID (212), chunk metadata (216A, 216M) and a timestamp (214). Each of the aforementioned portions of the object metadata (210) is discussed below.

In one or more embodiments of the invention, the object ID (212) is an identifier that specifies an object associated with the object entry (210A, 210N). The object ID (212) may be, for example, a string of numbers, letters, symbols, or any combination thereof that uniquely identifies the object.

In one or more embodiments of the invention, the timestamp (214) specifies a point in time that corresponds to a state of the object as specified by a set of chunk metadata. The timestamp (214) may be used to replay the object to a point in time. In one or more embodiments of the invention, the object is replayed to a point in time when the data associated with the object that was part of the object at the point in time is reconstructed to generate the object at the point in time. Said another way, the content of each object may vary over time and each time the object is modified a corresponding object entry is created where the object entry specifies chunk metadata for the chunks that make up the object at that point in time.

For example, at a first point in time, the object may include a first set of data, of which there is a first chunk and a second chunk. At a second point in time, the object may include a second set of data, of which there is a first chunk and a third chunk. The third chunk may be a modified version of the second chunk. The object may be replayed to the first point in time by obtaining the first chunk and the second chunk. The object may be replayed to the second point in time by obtaining the first chunk and the third chunk. For each point in time, there may be an object entry that specifies the object, the point in time, and each chunk used to replay the object.

In one or more embodiments of the invention, the chunk metadata (216A, 216M) each corresponds to a data chunk or parity chunk associated with the object at the point in time specified by the timestamp (214). The chunk metadata may include information about the data chunk or parity chunk such as, for example, a unique identifier (e.g., a fingerprint). The unique identifier may be, for example, a string of numbers, letters, symbols, or any combination thereof that uniquely identifies the chunk.

In one or more embodiments of the invention, an object entry (220A) is associated with more than one timestamp (224). In such embodiments, each chunk metadata (226A, 226M) may specify multiple chunks associated with a point in time. For example, after every iteration of an object (i.e., an object is associated with a new point in time), an object entry (220A, 220N) is updated with new chunk metadata (226A, 226M) that specifies the chunks of that iteration. In this manner, each object is associated with one object entry (220A, 220N) and each chunk metadata (226A, 226M) is associated with multiple chunks of an object at a point in time.

The object metadata (220) may be organized using other schemes without departing from the invention.

FIG. 3A shows a flowchart for storing data in a data cluster in accordance with one or more embodiments of the invention. The method shown in FIG. 3A may be performed by, for example, a data processor (122, FIG. 1B). Other components of the system illustrated in FIG. 1B may perform the method of FIG. 3A without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

In step 300, data is obtained from a host. The data may be, for example, an object. The object may be a file, a file fragment, a collection of files, or any other type of data without departing from the invention.

In step 302, an erasure coding procedure is performed on the data to generate data chunks and parity chunks. In one or more embodiments of the invention, the erasure coding procedure includes dividing the obtained data into portions, referred to as data chunks. Each data chunk may include any number of file fragments associated with the obtained data. The individual data chunks may then be combined (or otherwise grouped) into slices (also referred to as Redundant Array of Independent Disks (RAID) slices). One or more parity values are then calculated for each of the aforementioned slices. The number of parity values may vary based on the erasure coding algorithm that is being used as part of the erasure coding procedure. Non-limiting examples of erasure coding algorithms are RAID-3, RAID-4, RAID-5, and RAID-6. Other erasing coding algorithms may be used without departing from the invention. Continuing with the above discussion, if the erasing code procedure is implementing RAID-3, then a single parity value is calculated. The resulting parity value is then stored in a parity chunk. If erasure coding procedure algorithm requires multiple parity values to be calculated, then the multiple parity values are calculated with each parity value being stored in a separate data chunk.

As discussed above, the data chunks are used to generate parity chunks in accordance with the erasure coding procedure. More specifically, the parity chunks may be generated by applying a predetermined function (e.g., P Parity function, Q Parity Function), operation, or calculation to at least one of the data chunks. Depending on the erasure coding procedure used, the parity chunks may include, but are not limited to, P parity values and/or Q parity values.

In one embodiment of the invention, the P parity value is a Reed-Solomon syndrome and, as such, the P Parity function may correspond to any function that can generate a Reed-Solomon syndrome. In one embodiment of the invention, the P parity function is an XOR function.

In one embodiment of the invention, the Q parity value is a Reed-Solomon syndrome and, as such, the Q Parity function may correspond to any function that can generate a Reed-Solomon syndrome. In one embodiment of the invention, a Q parity value is a Reed-Solomon code. In one embodiment of the invention, Q=g₀·D₀+g₁·D₁+g₂D₂+ . . . +gₙ₋₁·Dₙ₋₁, where Q corresponds to the Q parity, g is a generator of the field, and the value of D corresponds to the data in the data chunks.

In one or more embodiments of the invention, the number of data chunks and parity chunks generated is determined by the erasure coding procedure, which may be specified by the host, by the data cluster, and/or by another entity.

In step 304, deduplication is performed on the data chunks to obtain deduplicated data chunks. Additionally, a storage metadata slice entry is generated based on the deduplication data chunks and the parity chunks. Further, an object slice entry is generated based data chunks (i.e., non-deduplicated data chunks) and the parity chunks with a timestamp.

In one or more embodiments of the invention, the deduplication is performed in the accelerator pool by identifying the data chunks of the obtained data and assigning a fingerprint to each data chunk. A fingerprint is a unique identifier that may be stored in metadata of the data chunk. The data processor performing the deduplication may generate a fingerprint for a data chunk and identify whether the fingerprint matches an existing fingerprint stored in storage metadata stored in the accelerator pool. If the fingerprint matches an existing fingerprint, the data chunk may be deleted, as it is already stored in the data cluster. If the fingerprint does not match any existing fingerprints, the data chunk may be stored as a deduplicated data chunk. Additionally, the fingerprint of each deduplicated data chunk is stored in a storage metadata slice entry of the storage metadata. A fingerprint (or other unique identifier) of each parity chunk is also generated and stored in the storage metadata slice entry.

In one or more embodiments of the invention, the deduplicated data chunks collectively make up the deduplicated data. In one or more embodiments of the invention, the deduplicated data chunks are the data chunks that were not deleted during deduplication.

In step 306, segment chunk metadata associated with the data chunks or parity chunks in each fault domain is identified. In one or more embodiments of the invention, the segment metadata is identified by analyzing the chunk identifiers and comparing the chunk identifiers to segment chunk metadata in the segment entries of the storage metadata.

In step 308, the deduplicated data chunks and parity chunk(s) are stored across data nodes in different fault domains in a non-accelerator pool based on the identified segment metadata. As discussed above, the deduplicated data chunks and the parity chunk(s) are stored in a manner that minimizes reads and writes from the non-accelerator pool. In one embodiment of the invention, this minimization is achieved by storing data chunks and parity chunks, which are collective referred to as a data slice (or slice), in the same manner as a prior version of the data slice. The data processor may use, as appropriate, storage metadata for the previously stored data chunks and parity chunks to determine where to store the data chunks and parity chunks in step 306.

More specifically, in one embodiment of the invention, if the deduplicated data chunks and parity chunks are the first version of a data slice (as opposed to a modification to an existing/previously stored data slice), then the deduplicated data chunks and parity chunks may be stored across the data nodes (each in a different fault domain) in the non-accelerator pool. The location in which the data chunk or parity chunk is stored is tracked using the storage metadata. The scenario does not require the data processor to use location information for previously stored data chunks and parity chunks.

However, if the deduplicated data chunks and parity chunks are the second version of a slice (e.g., a modification to a previously stored slice), then the deduplicated data chunks and parity chunks are stored across the nodes (each in a different fault domain) in the non-accelerator pool using prior stored location information. The information about the location in which the data chunk or parity chunk for the second version of the slice is stored in the storage metadata. The deduplicated data chunks and parity chunks may be stored based on the segment chunk metadata of the corresponding chunks. Specifically, the deduplicated data chunks and parity chunks in a segment may be stored contiguously with other chunks in the same segment.

For example, consider a scenario in which an object is being written to the data cluster. The object may be erasure coded to generate two slices, each of which includes three data chunks and one parity chunk. The first slice includes data chunks D11, D12, and D13 and parity chunk P11. The second slice includes data chunks D21, D22, and D23 and parity chunk P21. Each chunk in a slice may be allocated to a different fault domain. Specifically, D11 and D21 are stored in a first fault domain, D12 and D22 are stored in a second fault domain, D13 and D23 are stored in a third fault domain, and P11 and P21 are stored in a fourth fault domain. Based on this allocation of fault domains, D11 and D21 are associated with a first segment, D12 and D22 are associated with a second segment, D13 and D23 are associated with a third segment, and P11 and P21 are associated with a fourth segment. Each chunk (i.e., either parity chunk or deduplicated data chunk) in a segment may be stored contiguously with the other chunks in the segment in the persistent storage device of the corresponding fault domain.

Following the discussion of the above scenario, if the data node that obtains the deduplicated data chunk, which is a modified version of a prior stored deduplicated data chunk, then the data node may: (i) store the modified version of the deduplicated data chunk (i.e., the data node would include two versions of the data chunk) contiguously with the deduplicated data chunks of the corresponding segment, or (ii) store the modified version of the deduplicated data chunk in the same storage location as the prior version and delete the prior version of the deduplicated data chunk.

In one embodiment of the invention, the data processor includes functionality to determine whether a given data chunk is a modified version of a previously stored data chunk. Said another way, after the data is received from a host divided into data chunks and grouped into slices, the data processor includes functionality to determine whether a slice is a modified version of a prior stored slice. The data processor may use the fingerprints of the data chunks within the slice to determine whether the slice is a modified version of a prior stored slice. Other methods for determining whether a data chunk is a modified version of a prior stored data chunk and/or whether a slice is a modified version of a prior slice without departing from the invention.

In step 310, one or more segment entries are stored on the storage metadata based on the distribution of the deduplicated data chunks and parity chunks. In one or more embodiments of the invention, the segment entry (or entries) specifies the segment chunk metadata of each chunk distributed in step 308. The segment chunk metadata may include, for example, a chunk identifier, a storage location for the chunk, and the other chunks in the segment. The segment chunk metadata may specify other segment chunks without departing from the invention.

In step 312, a distribution of storage metadata and object metadata is initiated. In one or more embodiments of the invention, the storage metadata and the object metadata are distributed by generating a copy of the storage metadata that includes the storage metadata slice entry generated in step 304 and a copy of object metadata which includes the object entry and sending the copy of storage metadata and the copy of object metadata in the non-accelerator pool.

In one or more embodiments of the invention, the copy of storage metadata and the copy of object metadata are sent to a data node of a fault domain by the data processor. The data processor may further instruct the data node to distribute the copy of storage metadata and the copy of object metadata to other data nodes in the fault domain or to other data nodes in other fault domains. In this manner, a copy of the storage metadata is stored in multiple fault domains in the event of a storage metadata failure.

In one or more embodiments of the invention, the copy of storage metadata and object metadata is sent to multiple fault domains by the data processor. The data processor may send a copy of storage metadata and/or object metadata to one or more data nodes of each of the multiple fault domains. In this manner, a copy of the storage metadata and the object metadata is stored in multiple fault domains in the event of a storage metadata failure and/or an object metadata failure.

While FIG. 3A describes erasure coding and deduplicating the data, embodiments of the invention may be implemented where the data is only erasure coded and not deduplicated. In such embodiments, step 304 includes generating a storage metadata slice using non-deduplicated data chunks and parity chunks and step 306 includes distributing non-deduplicated data chunks and parity chunks

FIG. 3B shows a flowchart for replicating data to a second data cluster in accordance with one or more embodiments of the invention. The method shown in FIG. 3B may be performed by, for example, a sequence aware replicator (105, FIG. 1A). Other components of the system illustrated in FIG. 1A-1E may perform the method of FIG. 3B without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

In step 320, a storage replication request is obtained. The storage replication request may specify replicating data in a first data cluster to a second data cluster while maintaining the contiguity of segments in persistent storage devices of the second data cluster. The storage replication request may be obtained from an administrator that is operably connected to the two data clusters. Alternatively, the storage replication request is triggered by the sequence aware replicator based on a data replication policy implemented by the sequence aware replicator. The data replication policy may specify a schedule for performing the data replication.

In step 322, storage metadata from the data cluster is obtained. In one or more embodiments of the invention, the storage metadata specifies the storage location of each chunk in each fault domain of the first data cluster. The storage metadata may further specify the segments in each fault domain. As discussed above, each segment may include one or more chunks of an object that are stored in the same fault domain.

In one or more embodiments of the invention, the storage metadata is obtained from a data node in the accelerator pool. The sequence aware replicator may identify the data node that stores the storage metadata and send a request to obtain the storage metadata. The data node may send a response that includes the storage metadata.

In step 324, the fault domains in the second data cluster are identified. In one or more embodiments of the invention, the sequence aware replicator identifies which nodes in the data cluster are associated with which fault domains. The sequence aware replicator identifies the fault domains using, for example, a data node in the accelerator pool, which specifies the data nodes in each fault domain. The sequence aware replicator may associate each fault domain in the second data cluster to a fault domain in the first data cluster.

In step 326, a data cluster replication is performed using the storage metadata and the identified fault domains. In one or more embodiments of the invention, the data cluster replication is performed by selecting a segment entry in the storage metadata, identifying each chunk specified in the segment entry, determining a contiguous storage location in a corresponding fault domain in the second data cluster for the chunks, storing a copy of the chunks in the determined storage location, and repeating for each sequence entry specified in the storage metadata. In this manner, the contiguity of the segments are maintained in the second data cluster.

While the methods of FIG. 3A-3B are performed by data nodes of a data cluster with both an accelerator pool and a non-accelerator pool, embodiments of the invention may be implemented using a data cluster with only one tier of data nodes (e.g., a data cluster with only an accelerator pool or a data cluster with only a non-accelerator pool) without departing from the invention.

### Example

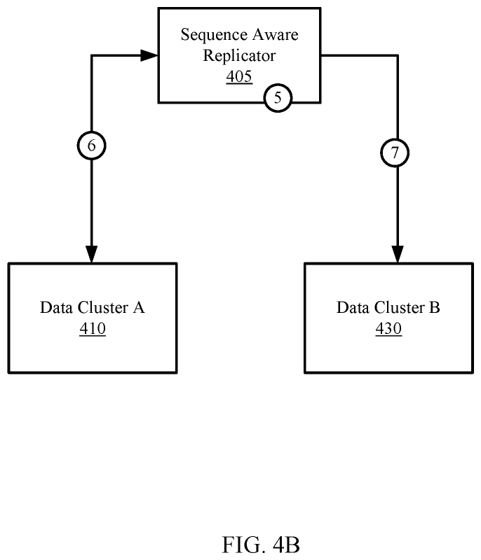

The following section describes an example. The example is not intended to limit the invention. The example is illustrated in FIGS. 4A-4B. Turning to the example, consider a scenario in which a data cluster obtains an object (e.g., a file) from a host. The host requests the object be stored in the data cluster (410) using a 3:1 erasure coding procedure. FIG. 4A shows a diagram a system in accordance with one or more embodiments of the invention. The host (400) sends the request to a data processor (412).

The data processor (412) performs the method of FIG. 3A to store the obtained object. Specifically, the data processor performs an erasure coding procedure on the object [2]. In this example, assume that the erasure coding procedure includes implementing RAID-3. The result of the erasure coding procedure is three slices each including three data chunks and a parity chunk. The data chunks and parity chunk may further go under a deduplication operation to obtain deduplicated data chunks. Because this object does not correspond to a previously-stored object, all data chunks are deduplicated data chunks and, as such, all need to be stored in the non-accelerator pool (420).

The first slice includes data chunks D11 (422A), D12 (422B), and D13 (422C) and parity chunk P11 (422D). The second slice includes data chunks D21 (424A), D22 (424B), and D23 (424C) and parity chunk P21 (424D). The third slice includes data chunks D31 (426A), D32 (426B), and D33 (426C) and parity chunk P31 (426D).

Prior to storing the data chunks and parity chunks, the data processor (412) identifies segments for the data chunks and the parity chunks based on the fault domains in which each chunk is assigned to be stored. A first segment (i.e., SID11) includes data chunks D11, D21, and D31 (422A, 424A, 426A). A second segment (i.e., SID21) includes data chunks D12, D22, and D32 (422B, 424B, 426B). A third segment (i.e., SID31) includes data chunks D13, D23, and D33 (422C, 424C, 426C). A fourth segment (i.e., SID41) includes parity chunks P11, P21, and P31 (422D, 424D, 426D).

The deduplicated data chunks and the parity chunk are stored across data nodes in the data cluster (410) [3]. Specifically, each of the three deduplicated data chunks and the parity chunk of each slice is stored in a unique fault domain. In this example, the chunks of the first segment (SID11) are stored contiguously in the same persistent storage device in node A (420A), which is associated with a first fault domain, the chunks of the second segment (SID21) are stored contiguously in the same persistent storage device in node B (420B), which is associated with a second fault domain, the chunks of the third segment (SID31) are stored contiguously in the same persistent storage device in node C (420C), which is associated with a third fault domain, and the chunks of the fourth segment (SID41) are stored contiguously in the same persistent storage device in node D (420D), which is associated with a fourth fault domain.

In addition to storing the deduplicated data chunks and the parity chunks, the data processor generates a storage metadata slice entry in storage metadata (414) and an object entry in object metadata (not shown) [4]. A timestamp and a unique identifier of each deduplicated data chunk and parity chunk are stored in the storage metadata slice entry and in the object entry. Further, three segment entries are stored in the storage metadata (412) that each specify a unique segment identifier and the corresponding chunks of each segment. Specifically, a first segment entry specifies the chunks of the first segment (SID11), a second segment entry specifies the chunks of the second segment (SID21), a third segment entry specifies the chunks of the third segment (SID31), and a fourth segment entry specifies the chunks of the fourth segment (SID41).

FIG. 4B shows a diagram of the example system. A data replication request is sent to a sequence aware replicator (405) [5]. The data replication request specifies replicating the data stored in data cluster A (410) to a second data cluster (430). The data replication request is sent by an administrator (not shown) of the data clusters (410, 430). The sequence aware replicator (405) in response to the data replication request, obtains the storage metadata from data cluster A (410) to be used during the replication [6].

After obtaining the storage metadata, the sequence aware replicator (405) utilizes the segment entries in the storage metadata to store the segments in contiguous sectors of hard drives in each fault domain in the second data cluster (430). In this manner, the storage organization of the data chunks and parity chunks in the first data cluster (410) is maintained in the second data cluster (430).

End of Example

As discussed above, embodiments of the invention may be implemented using computing devices. FIG. 5 shows a diagram of a computing device in accordance with one or more embodiments of the invention. The computing device (500) may include one or more computer processors (502), non-persistent storage (504) (e.g., volatile memory, such as random access memory (RAM), cache memory), persistent storage (506) (e.g., a hard disk, an optical drive such as a compact disk (CD) drive or digital versatile disk (DVD) drive, a flash memory, etc.), a communication interface (512) (e.g., Bluetooth interface, infrared interface, network interface, optical interface, etc.), input devices (510), output devices (508), and numerous other elements (not shown) and functionalities. Each of these components is described below.

In one embodiment of the invention, the computer processor(s) (502) may be an integrated circuit for processing instructions. For example, the computer processor(s) may be one or more cores or micro-cores of a processor. The computing device (500) may also include one or more input devices (510), such as a touchscreen, keyboard, mouse, microphone, touchpad, electronic pen, or any other type of input device. Further, the communication interface (512) may include an integrated circuit for connecting the computing device (500) to a network (not shown) (e.g., a local area network (LAN), a wide area network (WAN) such as the Internet, mobile network, or any other type of network) and/or to another device, such as another computing device.

In one embodiment of the invention, the computing device (500) may include one or more output devices (508), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (502), non-persistent storage (504), and persistent storage (506). Many different types of computing devices exist, and the aforementioned input and output device(s) may take other forms.

One or more embodiments of the invention may be implemented using instructions executed by one or more processors of the data management device. Further, such instructions may correspond to computer readable instructions that are stored on one or more non-transitory computer readable mediums.

One or more embodiments of the invention may improve the operation of one or more computing devices. More specifically, embodiments of the invention improve the efficiency of storing data in a data cluster and accessing such data by the host. The efficiency is improved by storing storage metadata that specifies where the data is stored and object metadata that specifies non-storage related metadata such as, for example, an object associated with the data. Embodiments of the invention include storing the data and tracking the storage location of the data to allow easier access to the data if a host requests to obtain the data.

Further, embodiments of the invention store such data in segments of contiguous chunks that, when accessed by a data processor, reduce the processing used to obtain such data. In this manner, the efficiency for obtaining, modifying, and storing the data in an object is increased. Thus, embodiments of the invention improve the efficiency of computing resources in one or more data clusters.

While the invention has been described above with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A method for managing data, the method comprising:
obtaining data from a host;
performing an erasure coding procedure to the data to obtain a plurality of slices, wherein each slice in the plurality of slices comprises a plurality of data chunks and at least one parity chunk;
generating a plurality of segment entries, wherein each segment entry in the plurality of segment entries specifies a segment;
generating a plurality of metadata slice entries, wherein each metadata slice entry in the plurality of metadata slice entries is associated with a slice in the plurality of slices;
storing the plurality of segment entries and the plurality of metadata slice entries in an accelerator pool in a first data cluster; and
storing, across a plurality of fault domains in the first data cluster, the plurality of data chunks and the at least one parity chunk of each slice in the plurality of slices based on the plurality of segment entries.

2. The method of claim 1, further comprising:
obtaining a storage replication request;
obtaining the plurality of segment entries from the accelerator pool;
performing a replication of the slices to obtain a plurality of slice replicas; and
storing the plurality of slice replicas in a second data cluster, wherein the second data cluster comprises a second plurality of fault domains.

3. The method of claim 2,
wherein the storing the plurality of slice replicas in the second data cluster comprises storing a segment in a first fault domain of the second plurality of fault domains,
wherein the segment comprises a data chunk of each slice in the plurality of slices, and
wherein the data chunks are stored contiguously in the first fault domain.

4. The method of claim 2,
wherein the storing the plurality of slice replicas in the second data cluster comprises storing a segment in a first fault domain of the second plurality of fault domains,
wherein the segment comprises a parity chunk of each slice in the plurality of slices, and
wherein the parity chunks are stored contiguously in the first fault domain.

5. The method of claim 1, wherein the data is associated with an object.

6. The method of claim 5, wherein the object is a file.

7. The method of claim 5, wherein each segment entry in the plurality of segment entries further specifies the object.

8. A non-transitory computer readable medium comprising computer readable program code, which when executed by a computer processor enables the computer processor to perform a method for managing data, the method comprising:
obtaining data from a host;
performing an erasure coding procedure to the data to obtain a plurality of slices, wherein each slice in the plurality of slices comprises a plurality of data chunks and at least one parity chunk;
generating a plurality of segment entries, wherein each segment entry in the plurality of segment entries specifies a segment;
generating a plurality of metadata slice entries, wherein each metadata slice entry in the plurality of metadata slice entries is associated with a slice in the plurality of slices;
storing the plurality of segment entries and the plurality of metadata slice entries in an accelerator pool in a first data cluster; and
storing, across a plurality of fault domains in the first data cluster, the plurality of data chunks and the at least one parity chunk of each slice in the plurality of slices based on the plurality of segment entries.

9. The non-transitory computer readable medium of claim 8, the method further comprising:
obtaining a storage replication request;
obtaining the plurality of segment entries from the accelerator pool;
performing a replication of the slices to obtain a plurality of slice replicas; and
storing the plurality of slice replicas in a second data cluster, wherein the second data cluster comprises a second plurality of fault domains.

10. The non-transitory computer readable medium of claim 9,
wherein the storing the plurality of slice replicas in the second data cluster comprises storing a segment in a first fault domain of the second plurality of fault domains,
wherein the segment comprises a data chunk of each slice in the plurality of slices, and
wherein the data chunks are stored contiguously in the first fault domain.

11. The non-transitory computer readable medium of claim 9,
wherein the storing the plurality of slice replicas in the second data cluster comprises storing a segment in a first fault domain of the second plurality of fault domains,
wherein the segment comprises a parity chunk of each slice in the plurality of slices, and
wherein the parity chunks are stored contiguously in the first fault domain.

12. The non-transitory computer readable medium of claim 8, wherein the data is associated with an object.

13. The non-transitory computer readable medium of claim 12, wherein the object is a file.

14. The non-transitory computer readable medium of claim 12, wherein each segment entry in the plurality of segment entries further specifies the object.

15. A data cluster, comprising:
an accelerator pool; and
a non-accelerator pool,
wherein a data processor of the accelerator pool comprises a processor and memory comprising instructions, which when executed by the processor perform a method, the method comprising:
obtaining data from a host;
performing an erasure coding procedure to the data to obtain a plurality of slices, wherein each slice in the plurality of slices comprises a plurality of data chunks and at least one parity chunk;
generating a plurality of segment entries, wherein each segment entry in the plurality of segment entries specifies a segment;
generating a plurality of metadata slice entries, wherein each metadata slice entry in the plurality of metadata slice entries is associated with a slice in the plurality of slices;
storing the plurality of segment entries and the plurality of metadata slice entries in an accelerator pool in a first data cluster; and
storing, across a plurality of fault domains in the first data cluster, the plurality of data chunks and the at least one parity chunk of each slice in the plurality of slices based on the plurality of segment entries.

16. The data cluster of claim 15, the method further comprising:
obtaining a storage replication request;
obtaining the plurality of segment entries from the accelerator pool;
performing a replication of the slices to obtain a plurality of slice replicas; and
storing the plurality of slice replicas in a second data cluster, wherein the second data cluster comprises a second plurality of fault domains.

17. The data cluster of claim 16,
wherein the storing the plurality of slice replicas in the second data cluster comprises storing a segment in a first fault domain of the second plurality of fault domains,
wherein the segment comprises a data chunk of each slice in the plurality of slices, and
wherein the data chunks are stored contiguously in the first fault domain.

18. The data cluster of claim 16,
wherein the storing the plurality of slice replicas in the second data cluster comprises storing a segment in a first fault domain of the second plurality of fault domains,
wherein the segment comprises a parity chunk of each slice in the plurality of slices, and
wherein the parity chunks are stored contiguously in the first fault domain.

19. The data cluster of claim 15, wherein the data is associated with an object.

20. The data cluster of claim 15, wherein each segment entry in the plurality of segment entries further specifies the object.
